(19) United States
(12) Patent Application Publication
(10) Pub. No.: US 2017/0226637 A1
(43) Pub. Date: Aug. 10, 2017

(54) PROCESS CHAMBER FOR DIELECTRIC GAPFILL

(71) Applicant: Applied Materials, Inc., Santa Clara, CA (US)

(72) Inventors: Dmitry Lubomirsky, Cupertino, CA (US); Qiwei Liang, Fremont, CA (US); Soonam Park, Sunnyvale, CA (US); Kien N. Chuc, San Francisco, CA (US); Ellie Yieh, San Jose, CA (US)

(73) Assignee: Applied Materials, Inc., Santa Clara, CA (US)

(21) Appl. No.: 15/581,324

(22) Filed: Apr. 28, 2017

Related U.S. Application Data
(63) Continuation of application No. 14/088,008, filed on Nov. 22, 2013.
Application No. 14/088,008 is a continuation of application No. 11/754,924, filed on May 29, 2007, now abandoned.
(60) Provisional application No. 60/803,499, filed on May 30, 2006.

(51) Int. Cl. C23C 16/455; C23C 16/40; H01J 37/32; C23C 16/52; H01L 21/02; H01L 21/762; C23C 16/505; C23C 16/458

(52) U.S. Cl. CPC C23C 16/45502; C23C 16/505; C23C 16/402; C23C 16/4586; C23C 16/45565; C23C 16/52; H01L 21/02274; H01L 21/02164; H01L 21/76224; C23C 16/45576; C23C 16/4584; H01J 37/32357; H01J 37/32082; H01J 37/3244; H01J 37/32724; H01J 2237/2001; H01J 2237/3321

(57) ABSTRACT

A system to form a dielectric layer on a substrate from a plasma of dielectric precursors is described. The system may include a deposition chamber, a substrate stage in the deposition chamber to hold the substrate, and a remote plasma generating system coupled to the deposition chamber, where the plasma generating system is used to generate a dielectric precursor having one or more reactive radicals. The system may also include a precursor distribution system that includes at least one top inlet and a plurality of side inlets. The top inlet may be positioned above the substrate stage and the side inlets may be radially distributed around the substrate stage. The reactive radical precursor may be supplied to the deposition chamber through the top inlet. An in-situ plasma generating system may also be included to generate the plasma in the deposition chamber from the dielectric precursors supplied to the deposition chamber.

### CROSS-REFERENCES TO RELATED APPLICATIONS

This application is a continuation of U.S. patent application Ser. No. 14/088,008, filed Nov. 22, 2013, which is a continuation of U.S. patent application Ser. No. 11/754,924, filed May 29, 2007, which claims the benefit of U.S. Provisional Application No. 60/803,499 filed May 30, 2006. This application is also related to co-assigned U.S. Provisional Application No. 60/803,489 by Munro et al, filed May 30, 2006 and titled “A METHOD FOR DEPOSITING AND CURING LOW-K FILMS FOR GAPFILL AND CONFORMAL FILM APPLICATIONS”. This application is also related to co-assigned U.S. Provisional App. No. 60/803,493, by Ingle et al, filed May 30, 2006 and titled “CHEMICAL VAPOR DEPOSITION OF HIGH QUALITY FLOW-LIKE SILICON DIOXIDE USING A SILICON CONTAINING PRECURSOR AND ATOMIC OXYGEN”. This application is also related to U.S. Provisional Application No. 60/803,481, by Chen et al, filed May 30, 2006 and titled “A NOVEL DEPOSITION-PLASMA CURE CYCLE PROCESS TO ENHANCE FILM QUALITY OF SILICON DIOXIDE”. The entire contents of the priority U.S. Provisional patent application and the related applications are herein incorporated by reference for all purposes.

### BACKGROUND OF THE INVENTION

As integrated circuit chipmakers continue increasing the density of circuit elements on each chip, filling the gaps that separate those elements becomes more challenging. The increased circuit element density has necessitated shorter widths between adjacent elements. As the width of these gaps shrink faster than their height, the ratio of height to width (known as the aspect ratio) proportionally increases. It is more difficult to fill a tall and narrow gap (i.e., a high aspect ratio gap) with a uniform film of dielectric material than a shallow and wide gap (i.e., a low aspect ratio gap).

One commonly encountered difficulty with filling high aspect ratio gaps is the formation of voids. In high aspect ratio gaps, there is a tendency of the dielectric material filling the gap to deposit at a faster rate around the top end of the gap. Often the dielectric material will close the top before the gap has been completely filled, leaving a void. Even when the top of the gap does not close prematurely, the uneven growth rate of the dielectric film down the sidewalls of the gap can create a weak seam in the middle of the gapfill. These seams can later result in cracks that adversely effect the physical integrity and dielectric properties of the device.

One technique to avoid the formation of voids and weak seams in dielectric gapfills is to fill the gap at a lower deposition rate. Lower deposition rates can give the dielectric material more time to redistribute on the inside surfaces of the gap to reduce the chances of excessive topside growth. A lower deposition rate may also be the result of increased etching or sputtering that occur at the same time as the dielectric deposition. For example, in HDPCVD dielectric material at the top corners of the gap etch away faster than material on the sidewalls and bottom portion of the gap. This increases the chances that the topside of the gap will remain open so the sidewalls and bottom can completely fill with dielectric material.

However, reducing the dielectric deposition rate also results in the deposition taking longer to complete. The longer deposition times decrease the rate at which substrate wafers are processed through the deposition chamber, resulting in a reduced efficiency for chamber.

Another technique to avoid formation of voids and weak seams is to enhance the flowability of the dielectric material that fills the gap. A flowable dielectric material can more easily migrate down the sidewalls and fill in voids at the center of the gap (sometimes referred to as “healing” the voids). Silicon oxide dielectrics are usually made more flowable by increasing the concentration of hydroxyl groups in the dielectric. However, there are challenges both with adding and removing these groups from the oxide without adversely affecting the final quality of the dielectric.

Thus, there is a need for improved systems and methods for filling short-width, high aspect ratio gaps with a void free dielectric film. These and other problems are addressed by the systems and methods of the present invention.

### BRIEF SUMMARY OF THE INVENTION

Embodiments of the invention include systems to form a dielectric layer on a substrate from a plasma of dielectric precursors. The systems may include a deposition chamber, a substrate stage in the deposition chamber to hold the substrate, and a remote plasma generating system coupled to the deposition chamber, where the plasma generating system is used to generate a dielectric precursor having one or more reactive radicals. The system may also include a precursor distribution system that includes at least one top inlet and a plurality of side inlets for introducing the dielectric precursors to the deposition chamber. The top inlet may be positioned above the substrate stage and the side inlets may be radially distributed around the substrate stage. The reactive radical precursor may be supplied to the deposition chamber through the top inlet. An in-situ plasma generating system may also be included to generate the plasma in the deposition chamber from the dielectric precursors supplied to the deposition chamber.

Embodiments of the invention also include additional systems to form a silicon dioxide layer on a silicon substrate. These systems may include a deposition chamber, and a substrate stage in the deposition chamber to hold the substrate, where the substrate stage rotates the substrate during the formation of the silicon oxide layer. The systems may also include a remote plasma generating system coupled to the deposition chamber, where the plasma generating system is used to generate an atomic oxygen precursor. They may still further include a precursor distribution system that includes: (i) at least one top inlet, where the top inlet is positioned above the substrate stage, and where the atomic oxygen precursor is supplied to the deposition chamber through the top inlet, and (ii) a plurality of side inlets for introducing one or more silicon-containing precursors to the deposition chamber, where the side inlets are radially distributed around the substrate stage.

Embodiments of the invention include still further systems to form a dielectric layer on a substrate from a plasma of dielectric precursors. These systems may include a deposition chamber comprising a top side made from a translucent material, a substrate stage in the deposition chamber to hold the substrate, and a remote plasma generating system coupled to the deposition chamber, where the plasma generating system is used to generate a dielectric precursor comprising a reactive radical. The systems may also include a radiative heating system to heat the substrate that includes at least one light source, where at least some of the light emitted from the light source travels through the top side of the deposition chamber before reaching the substrate. In addition, they may include a precursor distribution system that has at least one top inlet and a plurality of side inlets for introducing the dielectric precursors to the deposition chamber. The top inlet is coupled to the top side of the deposition chamber and positioned above the substrate stage, and the side inlets are radially distributed around the substrate stage. The reactive radical precursor may be supplied to the deposition chamber through the top inlet.

Embodiments of the invention may yet still further include additional systems to form a dielectric layer on a substrate from a plasma of dielectric precursors. The systems may include a deposition chamber, a substrate stage in the deposition chamber to hold the substrate, and a remote plasma generating system coupled to the deposition chamber, where the plasma generating system is used to generate a first dielectric precursor that includes one or more reactive radicals. The systems may also include a precursor distribution system that include a dual-channel showerhead positioned above the substrate stage. The showerhead may include a faceplate with a first set of openings through which the reactive radical precursor enters the deposition chamber, and a second set of openings through which a second dielectric precursor enters the deposition chamber. The precursors may not be mixed until entering the deposition chamber.

Embodiments of the invention may also include additional systems to form a dielectric layer on a substrate from a plasma of dielectric precursors. The systems may include a deposition chamber, a substrate stage in the deposition chamber to hold the substrate, and a remote plasma generating system coupled to the deposition chamber. The plasma generating system may be used to generate a dielectric precursor comprising a reactive radical. The systems may also include a precursor distribution system that have at least one top inlet, a perforated plate, and a plurality of side inlets for introducing the dielectric precursors to the deposition chamber. The perforated plate may positioned between the top inlet and side inlets, and the side inlets may be radially distributed around the substrate stage. The reactive radical precursor may be distributed in the deposition chamber through openings in the perforated plate. Additionally, an in-situ plasma generating system may be used to generate the plasma in the deposition chamber from the dielectric precursors supplied to the deposition chamber.

Embodiments of the invention may yet still further include systems to form a dielectric layer on a substrate. The systems may include a deposition chamber, a substrate stage in the deposition chamber to hold the substrate, and a remote plasma generating system coupled to the deposition chamber. The plasma generating system may be used to generate a first dielectric precursor comprising a reactive radical. The systems may also include a precursor distribution system having a plurality of side nozzles for introducing additional dielectric precursors to the deposition chamber. The side nozzles may be radially distributed around the substrate stage, and each of the nozzles may have a plurality of sidewall openings through which the additional dielectric precursors pass to enter the deposition chamber and mix with the first dielectric precursor.

Embodiments of the invention may also further include additional systems to form a dielectric layer on a substrate. The systems may include a deposition chamber, a substrate stage in the deposition chamber to hold the substrate, and a remote plasma generating system coupled to the deposition chamber. The plasma generating system may be used to generate a first dielectric precursor comprising a reactive radical. The systems may also include a precursor distribution system having a radial precursor manifold for introducing additional dielectric precursors to the deposition chamber, where the manifold may include a plurality of radially distributed conduits positioned above the substrate stage and axially aligned around the substrate stage. The conduits may include a plurality of sidewall openings through which the additional dielectric precursors pass to enter the deposition chamber and mix with the first dielectric precursor.

Additional embodiments and features are set forth in part in the description that follows, and in part will become apparent to those skilled in the art upon examination of the specification or may be learned by the practice of the invention. The features and advantages of the invention may be realized and attained by means of the instrumentalities, combinations, and methods described in the specification.

### BRIEF DESCRIPTION OF THE DRAWINGS

FIG. 1 shows a simplified schematic for process systems according to embodiments of the invention;

FIG. 2A shows a cross-section of a exemplary process system according to embodiments of the invention;

FIG. 2B shows a cross-section of another exemplary process system according to embodiment of the invention;

FIG. 2C shows another cross-section view of the process system shown in FIG. 2B;

FIG. 2D shows a cross-section of a portion of a deposition chamber that includes a pressure equalization channel and openings in the pumping liner to reduce asymmetric pressure effects according to embodiments of the invention;

FIGS. 3A-C show configurations of a top baffle in a process system according to embodiments of the invention;

FIG. 3D shows a configuration of a top inlet and perforated plate in a process system according to embodiments of the invention;

FIG. 3E shows a precursor flow distribution for oxygen-containing and silicon-containing precursors in a process system that includes a perforated top plate according to embodiments of the invention;

FIG. 4A shows a configuration of side nozzles in a process system according to embodiments of the invention;

FIG. 4B shows another configuration of side nozzles with capped ends and a plurality of opening along the lengths of the nozzle tubes according to embodiments of the invention;

FIG. 4C shows a cross-sectional diagram of precursor flow through a capped side nozzle like one that is shown in FIG. 4B;

FIG. 4D shows a design for a one-piece precursor distribution manifold according to embodiments of the invention;

FIG. 4E shows an enlarged portion of the precursor distribution manifold shown in FIG. 4D;

FIGS. 5A & B show cross-sectional views of a process system having a radially concentric configuration of radiative heating elements according to embodiments of the invention;

FIGS. 5C & D show cross-sectional views of a process system having a parallel configuration for a plurality of radiative heating elements according to embodiments of the invention;

FIGS. 5E & F show cross-sectional views of a process system having a dual socket configuration of radiative heating elements according to embodiments of the invention;

FIG. 6 shows an arrangement of deposition, baking and curing chambers according to embodiments of the invention;

FIG. 7A shows a cross-section of a showerhead with independent gas flow channels according to embodiments of the invention;

FIG. 7B shows a cross-section of a showerhead with independent gas flow and plasma zones according to embodiments of the invention;

FIG. 8A shows a cross-sectional portion of a showerhead where process gases are provided through independent channels that include concentric holes in the faceplate;

FIG. 8B shows a picture of the surface of a faceplate having a concentric hole design according to embodiments of the invention;

FIG. 8C shows a cross-sectional another cross-sectional portion of a showerhead where process gases are provided through independent parallel channels formed in the faceplate; and

FIG. 8D shows a cross-sectional portion of a showerhead that flows a process gas from the edge to the center of the showerhead according to embodiments of the invention.

### DETAILED DESCRIPTION OF THE INVENTION

Systems are described for depositing a flowable CVD dielectric film on a substrate. These dielectric films may be used for STI, IMD, ILD, OCS, and other applications. The systems may include a reactive species generation system that supplies reactive radical species to a deposition chamber, where the species chemically react with other deposition precursors and form a flowable film of dielectric on a deposition surface of the substrate. For example the system may form a layer on a substrate from excited oxygen by a remote plasma source and organo-silane types of precursors. The systems may also include substrate temperature control systems that can both heat and cool the substrate during a deposition. For example, the flowable oxide film may be deposited on the substrate surface at low temperature (e.g., less that 100° C.) which is maintained by cooling the substrate during the deposition. Following the film deposition, the temperature control system may heat the substrate to perform an anneal.

The described systems may further include substrate motion and positioning systems to rotate the substrate during the deposition and translate it towards or away from the precursor distribution system (e.g., the nozzles and/or showerhead that distribute the precursors in the deposition chamber). Rotation of the substrate may be used to distribute the flowable oxide film more evenly over the substrate surface, similar to a spin-on technique. Translation of the substrate may be used to change the film deposition rate by changing the distance between the substrate deposition surface and the precursors entry into the deposition chamber.

The systems may further have a substrate irradiation system that can irradiate the deposited film with light. Embodiments include irradiating the surface with UV light to cure the deposited film, and irradiating the substrate to raise its temperature, for example in a rapid thermal anneal type process.

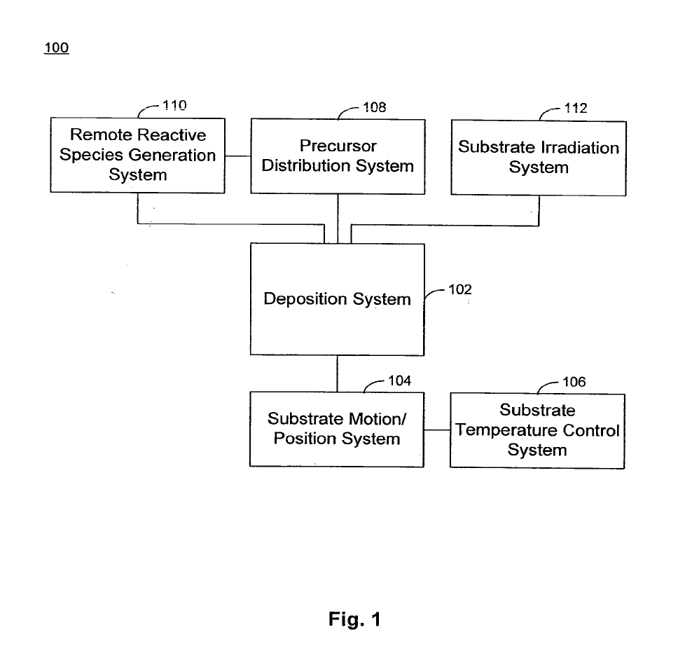

FIG. 1 provides a simplified schematic of how components of the system 100 can be integrated in embodiments of the invention. The system 100, includes a deposition system 102 where precursors can chemically react and form a flowable dielectric film (e.g., a silicon oxide film) on a substrate wafer in the deposition chamber. The deposition system 102 may include coils and/or electrodes that generate radio frequency power inside the deposition chamber to create a plasma. The plasma may enhance the reaction rates of the precursors, which may in turn increases the deposition rate of the flowable dielectric material on the substrate.

As the flowable oxide is being deposited, a substrate motion and positioning system 104 may be used to rotate the substrate in order to expose different parts of the substrate to the flow of precursors in a more uniform manner. This may make the mass transfer of species in the precursors more uniform. It may also spread low viscosity films more widely over the deposition surface of the substrate. The positioning system 104 may include or be coupled to a rotatable and vertically translatable substrate pedestal.

The system 100 may also include a substrate temperature control system 106 that is operable to raise and lower the temperature of the substrate. The temperature control system 106 may be coupled to the substrate pedestal and transfer heat to and from the substrate through direct contact or other thermal coupling of the substrate to the substrate pedestal. The temperature system 106 may use circulating fluids (e.g., water) to control the substrate temperature, and/or electrical materials (e.g., resistive heating filaments) that supply heat energy by running electric current through the materials.

The precursors used to form the flowable dielectric film may be supplied by a precursor distribution system 108. Examples of distribution systems 108 include baffle and nozzle systems to flow precursors from the top and sides of the deposition chamber in deposition system 102. Examples also include a showerhead with a plurality of openings through which the precursor gases are distributed into the deposition chamber. In additional examples, the system 108 may include a gas ring without nozzles that has a plurality of openings through which precursors flow into the deposition chamber.

The distribution system 108 may be configured to independently flow two or more precursors into the deposition chamber. In these configurations, at least one pair of the precursors do not contact each other until they exit the distribution system to mix and react in the deposition chamber. For example, a reactive species generating system 110 may generate a highly reactive species, such as atomic oxygen, which does not mix or react with other precursors, such as a silicon containing precursor, until flowing out of the precursor distribution system 108 and into deposition system 102.

The precursors used in system 100 may include precursors for forming a flowable dielectric oxide film. The oxide film precursors may include a reactive species precursor such as radical atomic oxygen, as well as other oxidizing precursors such as molecular oxygen (O₂), ozone (O₃), water vapor, hydrogen peroxide (H₂O₂), and nitrogen oxides (e.g., N₂O, NO₂, etc.) among other oxidizing precursors. The oxide film precursors also include silicon-containing precursors such as organo-silane compounds including TMOS, TriMOS, TEOS, OMCTS, HMDS, TMCTR, TMCTS, OMTS, TMS, and HMDSO, among others. The silicon-containing precursors may also include silicon compounds that don't have carbon, such as silane (SiH₄). If the deposited oxide film is a doped oxide film, dopant precursors may also be used such as TEB, TMB, B₂H₆, TEPO, PH₃, P₂H₆, and TMP, among other boron and phosphorous dopants. If the film is a dielectric silicon nitride or silicon oxynitride, then nitrogen-containing precursors may also be used, such as ammonia, BTBAS, TDMAT, DBEAS, and DADBS, among others. For some film depositions, halogens may also be used, for example as catalysts. These halogen precursors may include hydrogen chloride (HCl), and chlorosilanes, such as chloroethylsilane. Other acid compounds may also be used such as organic acids (e.g., formic acid). All of these deposition precursors may be transported through the distribution system 108 and deposition system 102 by carrier gases, which may include helium, argon, nitrogen (N₂), and hydrogen (H₂), among other gases.

The system 100 may also include a substrate irradiation system 112 that may bake and/or cure the flowable dielectric material deposited on the substrate surface. The irradiation system 112 may include one or more lamps that can emit UV light which may be used, for example, to cure the film by decomposing silanol groups in the dielectric material into silicon oxide and water. The irradiation system may also include heat lamps for baking (i.e., annealing) the flowable films to remove water vapor and other volatile species from the film and make it more dense.

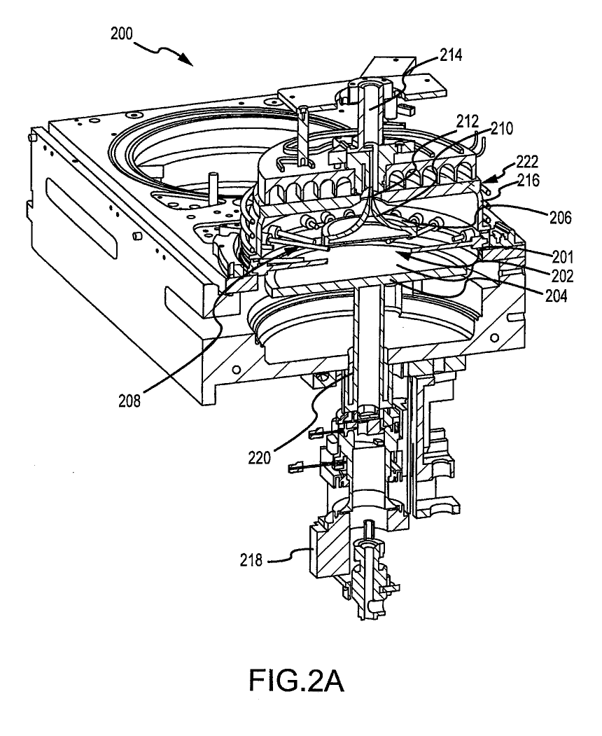

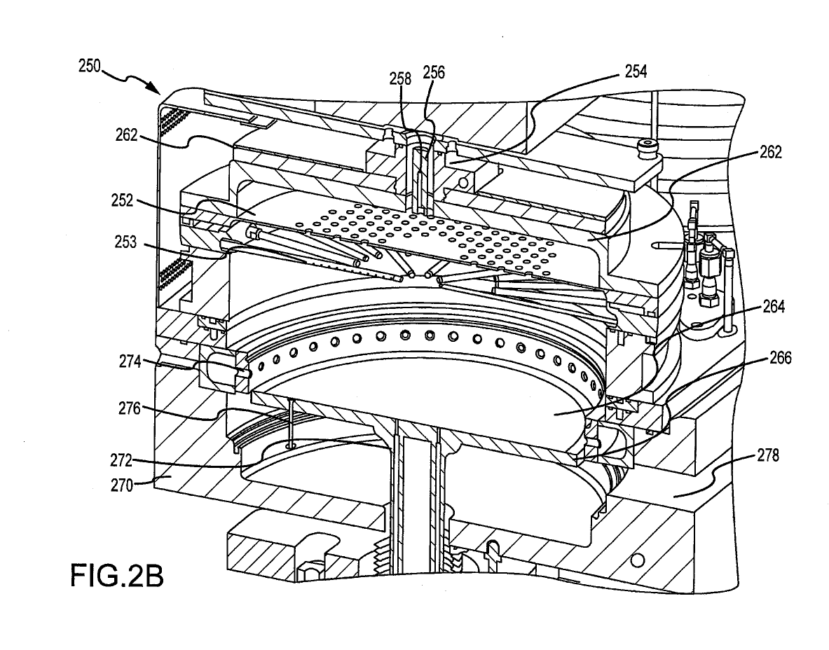

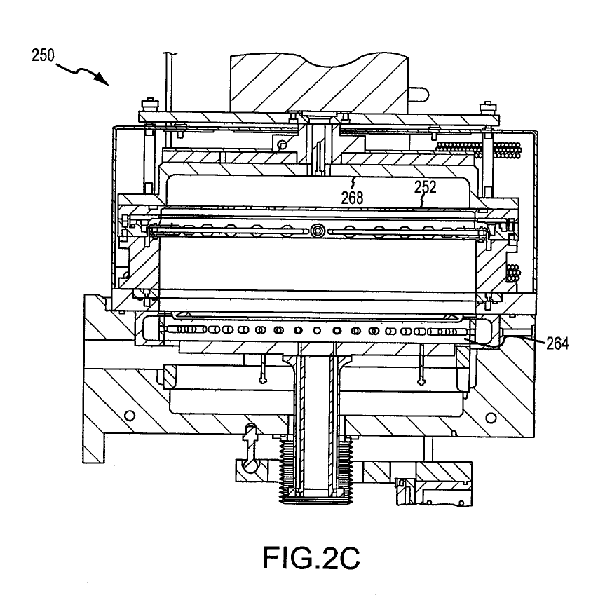

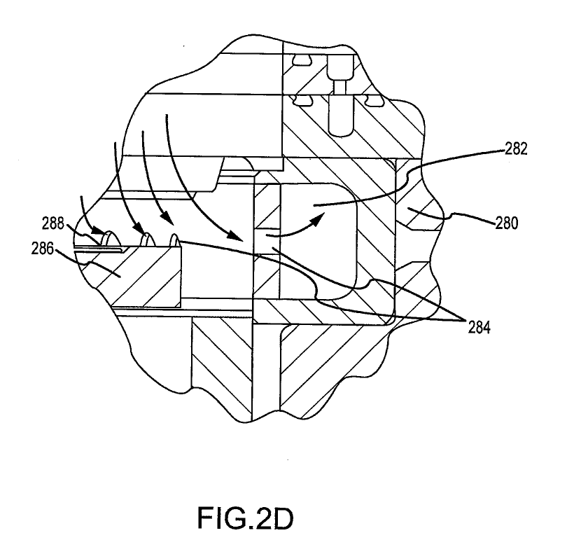

Referring now to FIG. 2A, a cross-section of an exemplary processing system 200 according to embodiments of the invention is shown. The system 200 includes a deposition chamber 201 where precursors chemically react and deposit a flowable dielectric film on a substrate wafer 202. The wafer 202 (e.g., a 200 mm, 300 mm, 400 mm, etc. diameter semiconductor substrate wafer) may coupled to a rotatable substrate pedestal 204 that is also vertically translatable to position the substrate 202 closer or further away from the overlying precursor distribution system 206. The pedestal may rotate the substrate wafer at a rotational speed of about 1 rpm to about 2000 rpm (e.g., about 10 rpm to about 120 rpm). The pedestal may vertically translate the substrate a distance from, for example, about 0.5 mm to about 100 mm from the side nozzles 208 of the precursor distribution system.

The precursor distribution system 206 includes a plurality of radially distributed side nozzles 208, each having one of two different lengths. In additional embodiments (not shown) the side nozzles may eliminated to leave a ring of openings distributed around the wall of the deposition chamber. The precursors flow through these openings into the chamber.

The distribution system 206 may also include a conically-shaped top baffle 210 that may be coaxial with the center of the substrate pedestal 204. A fluid channel 212 may run through the center of the baffle 210 to supply a precursor or carrier gas with a different composition than the precursor flowing down the outside directing surface of the baffle.

The outside surface of the baffle 210 may be surrounded by a conduit 214 that directs a reactive precursor from a reactive species generating system (not shown) that is positioned over the deposition chamber 201. The conduit 214 may be a straight circular tube with one end opening on the outside surface of baffle 210 and the opposite end coupled to the reactive species generating system.

The reactive species generating system may be a remote plasma generating system (RPS) that generates the reactive species by exposing a more stable starting material to the plasma. For example, the starting material may be a mixture that includes molecular oxygen (or ozone). The exposure of this starting material to a plasma from the RPS causes a portion of the molecular oxygen to dissociate into atomic oxygen, a highly reactive radical species that will chemically react with an organo-silicon precursor (e.g., OMCTS) at much lower temperatures (e.g., less than 100° C.) to form a flowable dielectric on the substrate surface. Because the reactive species generated in the reactive species generating system are often highly reactive with other deposition precursors at even room temperature, they may be transported in an isolated gas mixture down conduit 214 and dispersed into the reaction chamber 201 by baffle 210 before being mixed with other deposition precursors.

System 200 may also include rf coils (not shown) coiled around the dome 216 of the deposition chamber 201. These coils can create an inductively-coupled plasma in the deposition chamber 201 to further enhance the reactivity of the reactive species precursor and other precursors to deposit the fluid dielectric film on the substrate. For example, a gas flow containing reactive atomic oxygen dispersed into the chamber by baffle 210 and an organo-silicon precursor from channel 212 and/or one or more of the side nozzles 208 may be directed into a plasma formed above the substrate 202 by the rf coils. The atomic oxygen and organo-silicon precursor rapidly react in the plasma even at low temperature to form a highly flowable dielectric film on the substrate surface.

The substrate surface itself may be rotated by the pedestal 204 to enhance the uniformity of the deposited film. The rotation plane may be parallel to the plane of the wafer deposition surface, or the two planes may be partially out of alignment. When the planes are out of alignment, the rotation of the substrate 204 may create a wobble that can generate fluid turbulence in the space above the deposition surface. In some circumstances, this turbulence may also enhance the uniformity of the dielectric film deposited on the substrate surface. The pedestal 204 may also include recesses and/or other structures that create a vacuum chuck to hold the wafer in position on the pedestal as it moves. Typical deposition pressures in the chamber range from about 0.05 Torr to about 200 Torr total chamber pressure (e.g., 1 Torr), which makes a vacuum chuck feasible for holding the wafer in position.

Pedestal rotation may be actuated by a motor 218 positioned below the deposition chamber 201 and rotationally coupled to a shaft 220 that supports the pedestal 204. The shaft 220 may also include internal channels (not shown) that carry cooling fluids and/or electrical wires from cooling/heating systems below the deposition chamber (not shown) to the pedestal 204. These channels may extend from the center to the periphery of the pedestal to provide uniform cooling and/or heating to the overlying substrate wafer 202. They also may be designed to operate when the shaft 220 and substrate pedestal 204 are rotating and/or translating. For example, a cooling system may operate to keep the substrate wafer 202 temperature less than 100° C. during the deposition of a flowable oxide film while the pedestal is rotating.

The system 200 may further include an irradiation system 222 positioned above the dome 216. Lamps (not shown) from the irradiation system 222 may irradiate the underlying substrate 202 to bake or anneal a deposited film on the substrate. The lamps may also be activated during the deposition to enhance a reaction in the film precursors or deposited film. At least the top portion of the dome 216 is made from a translucent material capable of transmitting a portion of the light emitted from the lamps.

FIG. 2B shows another embodiment of an exemplary processing system 250 where a perforated plate 252 positioned above the side nozzles 253 distributes the precursors from a top inlet 254. The perforated plate 252 distributes the precursors through a plurality of openings 260 that traverse the thickness of the plate. The plate 252 may have, for example from about 10 to 2000 openings (e.g., 200 openings). In the embodiment shown, the perforated plate may distribute oxidizing gases, such a atomic oxygen and/or other oxygen-containing gases like TMOS or OMCTS. In the illustrated configuration, the oxidizing gas is introduced into the deposition chamber above the silicon containing precursors, which are also introduced above the deposition substrate.

The top inlet 254 may have two or more independent precursor (e.g., gas) flow channels 256 and 258 that keep two or more precursors from mixing and reaction until they enter the space above the perforated plate 252. The first flow channel 256 may have an annular shape that surrounds the center of inlet 254. This channel may be coupled to an overlying reactive species generating unit (not shown) that generates a reactive species precursor which flows down the channel 256 and into the space above the perforated plate 252. The second flow channel 258 may be cylindrically shaped and may be used to flow a second precursor to the space above the plate 252. This flow channel may start with a precursor and/or carrier gas source that bypasses a reactive species generating unit. The first and second precursors are then mixed and flow through the openings 260 in the plate 252 to the underlying deposition chamber.

The perforated plate 252 and top inlet 254 may be used to deliver an oxidizing precursor to the underlying space in the deposition chamber 270. For example, first flow channel 256 may deliver an oxidizing precursor that includes one or more of atomic oxygen (in either a ground or electronically excited state), molecular oxygen (O₂), N₂O, NO, NO₂, and/or ozone (O₃). The oxidizing precursor may also include a carrier gas such as helium, argon, nitrogen (N₂), etc. The second channel 258 may also deliver an oxidizing precursor, a carrier gas, and/or an additional gas such as ammonia (NH₃).

The system 250 may be configured to heat different parts of the deposition chamber to different temperatures. For example, a first heater zone may heat the top lid 262 and perforated plate 252 to a temperature in a range of about 70° C. to about 300° C. (e.g., about 160° C.). A second heater zone may heat the sidewalls of the deposition chamber above the substrate wafer 264 and pedestal 266 to the same or different temperature than the first heater zone (e.g., up to about 300° C.). The system 250 may also have a third heater zone below the substrate wafer 264 and pedestal 266 to the same or different temperature than the first and/or second heater zones (e.g., about 70° C. to about 120° C.). In addition, the pedestal 266 may include heating and/or cooling conduits (not shown) inside the pedestal shaft 272 that set the temperature of the pedestal and substrate to from about −40° C. to about 200° C. (e.g., about 100° C. to about 160° C., less than about 100° C., about 40° C., etc.). During processing, the wafer 264 may be lifted off the pedestal 266 with lift pins 276, and may be located about the slit valve door 278.

The system 250 may additional include a pumping liner 274 (i.e., a pressure equalization channel to compensate for the non-symmetrical location of the pumping port) that includes multiple openings in the plenum of the wafer edge, and/or located on the cylindrical surface around the wafer edge, and/or on the conical shaped surface located around the wafer edge. The openings themselves may be circular as shown in the liner 274, or they may be a different shape, such a slot (not shown). The openings may have a diameter of, for example, about 0.125 inches to about 0.5 inches. The pumping liner 274 may be above or below the substrate wafer 264 when the wafer is being processed. It may also be located above the slit valve door 278.

FIG. 2C shows another cross-section view of the process system 250 shown in FIG. 2B. FIG. 2C illustrates some dimensions for the system 250, including a main chamber inner wall diameter ranging from about 10 inches to about 18 inches (e.g., about 15 inches). It also shows a distance between the substrate wafer 264 and the side nozzles of about 0.5 inches to about 8 inches (e.g., about 5.1 inches). In addition, the distance between the substrate wafer 264 and the perforated plate 252 may range from about 0.75 inches to about 12 inches (e.g., about 6.2 inches). Furthermore, the distance between the substrate wafer and the top inside surface of the dome 268 may be about 1 inch to about 16 inches (e.g., about 7.8 inches).

FIG. 2D shows a cross-section of a portion of a deposition chamber 280 that includes a pressure equalization channel 282 and openings in the pumping liner 284. In the configuration shown, the channels 282 and openings 284 may be located below an overlying showerhead, top baffle and/or side nozzles, and level with or above the substrate pedestal 286 and wafer 288.

The channels 282 and openings 284 can reduce asymmetric pressure effects in the chamber. These effects may be caused by the asymmetric location of the pumping port that can create a pressure gradient in the deposition chamber 280. For example, a pressure gradient underneath the substrate pedestal 286 and/or substrate wafer 288 may cause the pedestal and wafer to tilt, which may cause irregularities in the deposition of the dielectric film. The channel 282 and pumping liner openings 284 reduce the pressure gradients in the chamber 280 and help stabilize the position of the pedestal 286 and wafer 288 during a deposition.

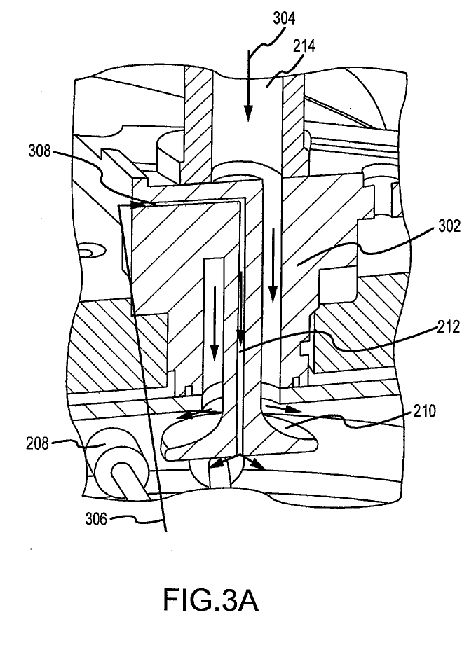

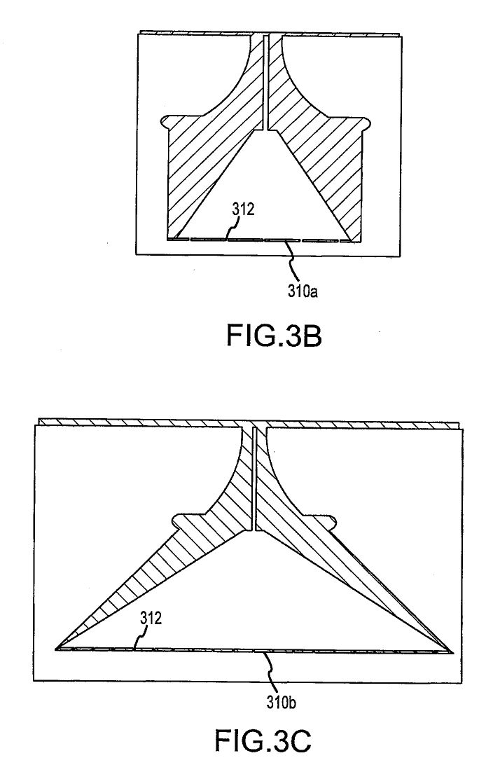

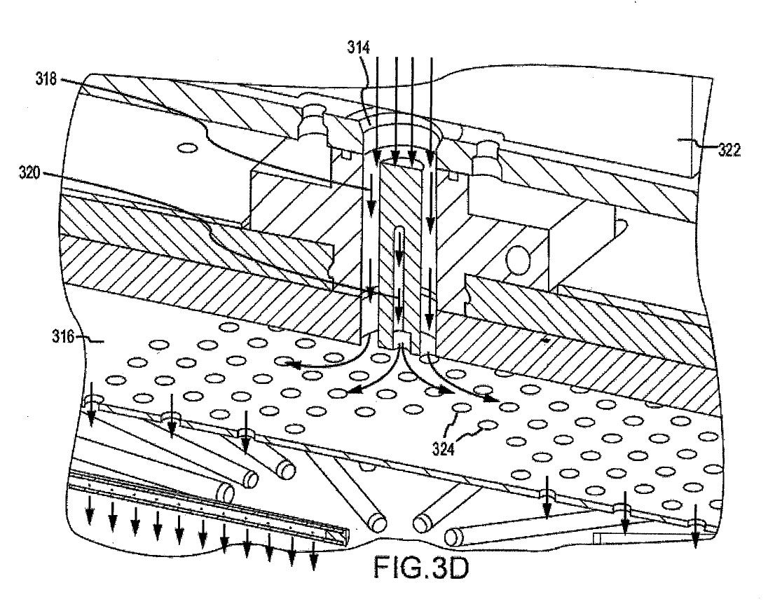

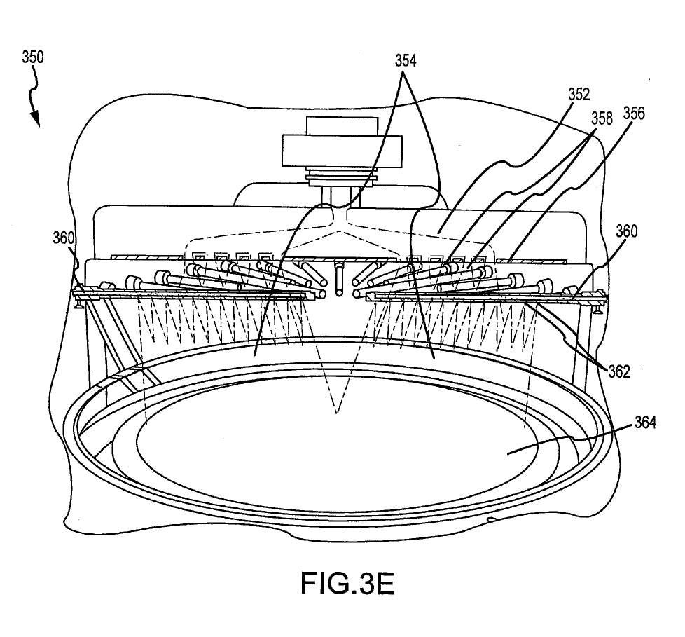

FIG. 3A shows a view of an embodiment of a top portion 302 of the precursor distribution system 206 in FIG. 2A, including channel 212 formed down the center of baffle 210 whose upper portion is surrounded by conduit 214. FIG. 3A shows a reactive species precursor 304 flowing down conduit 214 and over an outer surface of baffle 210. As the reactive species precursor 304 reaches the conically shaped end of the baffle 210 closest to the deposition chamber, it gets radially distributed into the chamber, where the reactive species 304 makes first contact with second precursor 306.

The second precursor 306 may be an organo-silane precursor and may also include a carrier gas. The organo-silane precursor may include one or more compounds such as TMOS, TriMOS, TEOS, OMCTS, HMDS, TMCTR, TMCTS, OMTS, TMS, and HMDSO, among other precursors. The carrier gas may include one or more gases such as nitrogen (N₂), hydrogen (H₂), helium, and argon, among other carrier gases. The precursor is fed from a source (not shown) connected to precursor feed line 308, which is also coupled to channel 212. The second precursor 306 may flow down center channel 212 without being exposed to the reactive species 304 that flows over the outside surface of baffle 210. When the second precursor 306 exits the bottom of baffle 210 into the deposition chamber, it may mix for the first time with the reactive species 304 and additional precursor material supplied by the side nozzles 208.

The reactive precursor 304 that flows down conduit 214 be generated in a reactive species generation unit (not shown), such as a RPS unit. An RPS unit, for example, can create plasma conditions that are well suited for forming the reactive species. Because the plasma in the RPS unit is remote from a plasma generated in the deposition chamber, different plasma conditions can be used for each component. For example, the plasma conditions (e.g., rf power, rf frequencies, pressure, temperature, carrier gas partial pressures, etc.) in the RPS unit for forming atomic oxygen radicals from oxygen precursors such as O₂, O₃, N₂O, etc., may be different from the plasma conditions in the deposition chamber where the atomic oxygen reacts with one or more silicon containing precursors (e.g., TMOS, TriMOS, OMCTS, etc.) and forms the flowable dielectric film on the underlying substrate.

FIG. 3A shows a dual-channel top baffle designed to keep the flow of a first and second precursor independent of each other until they reach the deposition chamber. Embodiments of the invention also include configurations for the independent flow of three or more precursors into the chamber. For example, configurations may include two or more independent channels like channel 212 running through and inner portion of baffle 210. Each of these channels may carry precursors that flow independently of each other until reaching the deposition chamber. Additional examples may include a single-channel baffle 210 that has no channel running through its center. In these embodiments, second precursor 306 enters the deposition chamber from side nozzles 208 and reacts with the reactive precursor 304 radially distributed by baffle 210 into the chamber.

FIGS. 3B and 3C show additional embodiments of the baffle 210. In both FIGS. 3B and 3C, channel 212 opens into a conically shaped volume that is defined on its bottom side (i.e., the side closest to the deposition chamber) by a perforated plate 310a-b. The precursor exits this volume through the openings 312 in the perforated plate. FIGS. 3B and 3C, show how the angle between the sidewall and bottom plate 310a-b can vary. The figures also illustrate variations in the shape of the outer conical surface over which the precursor flows as it enters the deposition chamber.

FIG. 3D shows a configuration of a top inlet 314 and perforated plate 316 that is used in lieu of a top baffle to distribute precursors from the top of a deposition chamber. In the embodiment shown, the top inlet 314 may have two or more independent precursor flow channels 318 and 320 that keep two or more precursors from mixing and reaction until they enter the space above the perforated plate 316. The first flow channel 318 may have an annular shape that surrounds the center of inlet 314. This channel may be coupled to an overlying reactive species generating unit 322 that generates a reactive species precursor which flows down the channel 318 and into the space above the perforated plate 316. The second flow channel 320 may be cylindrically shaped and may be used to flow a second precursor to the space above the plate 316. This flow channel may start with a precursor and/or carrier gas source that bypasses a reactive species generating unit. The first and second precursors are then mixed and flow through the openings 324 in the plate 316 to the underlying deposition chamber.

FIG. 3E shows a precursor flow distribution for oxygen-containing 352 and silicon-containing precursors 354 in a process system 350 that includes a perforated top plate 356 according to embodiments of the invention. Like FIG. 3D, an oxygen-containing gas such as radical atomic oxygen is generated by a remote plasma system (not shown) and introduced through the top of the deposition chamber to the space above the perforated plate 356. The reactive oxygen species then flow through openings 358 in the perforated plate 356 down into a region of the chamber where silicon-containing precursors 354 (e.g., organo-silane and/or silanol precursors) are introduced to the chamber by side nozzles 360.

The side nozzles 360 shown in FIG. 3E are capped at their distal ends extending into the deposition chamber. The silicon-containing precursors exit the side nozzles 360 through a plurality of openings 362 formed in the sidewalls of the nozzle conduits. These openings 362 may be formed in the part of nozzle sidewalls facing the substrate wafer 364 to direct the flow of the silicon-containing precursors 354 towards the wafer. The openings 362 may be co-linearly aligned to direct the flow of precursor 354 in the same direction, or they may be formed at different radial positions along the sidewalls to direct the precursor flow at different angles with respect to the underlying wafer. Embodiments of the capped side nozzles 360 include openings 362 with a diameter from about 8 mils to about 200 mils (e.g., about 20 mils to about 80 mils), and a spacing between openings of about 40 mils to about 2 inches (e.g., about 0.25 inches to about 1 inch). The number of openings 262 may vary with respect to the spacing between openings and/or the length of the side nozzle.

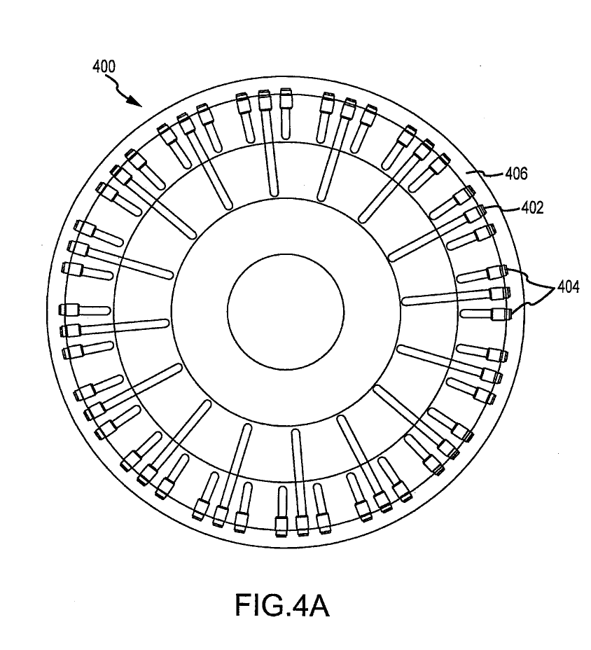

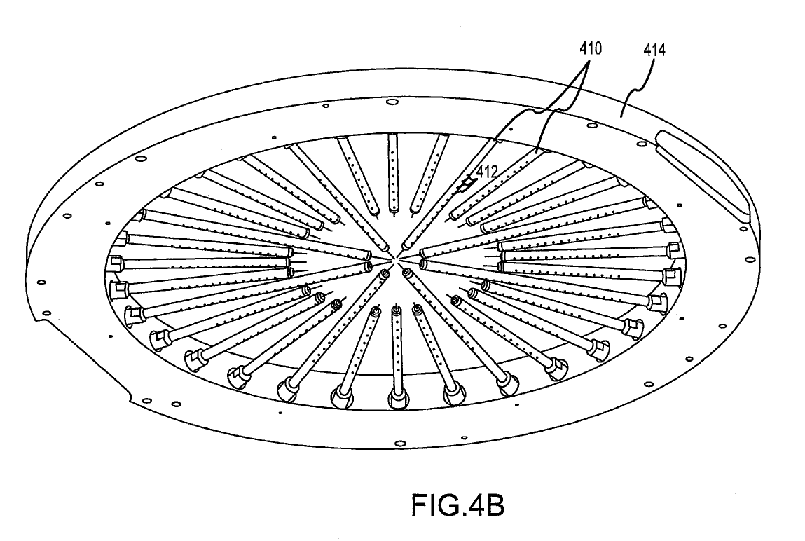

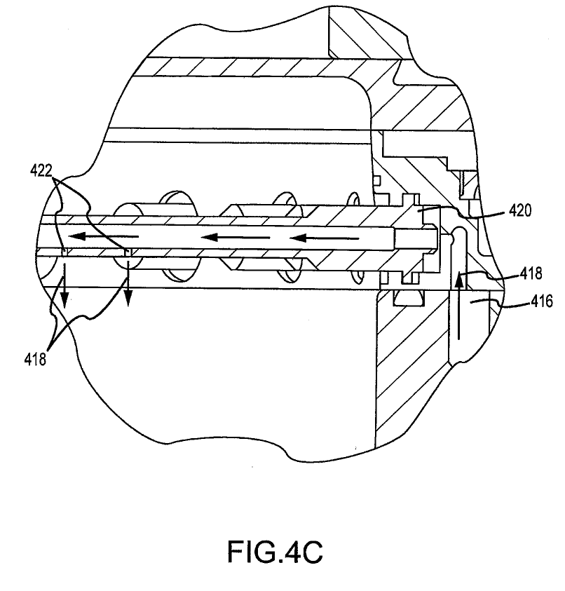

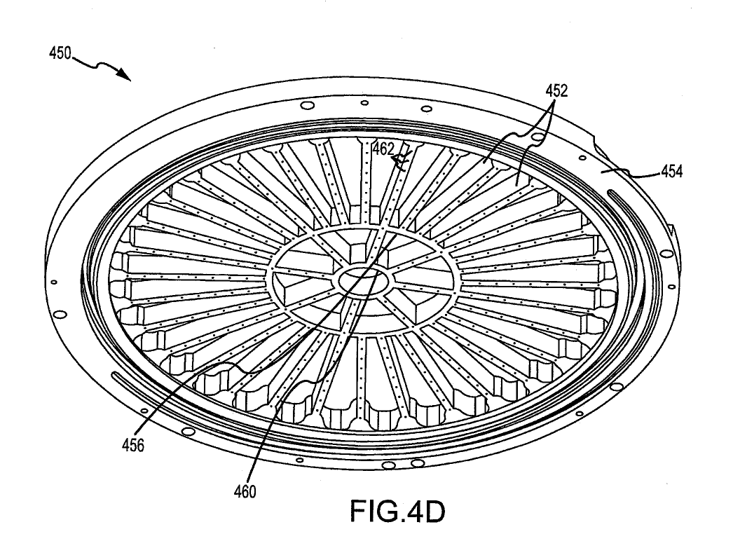

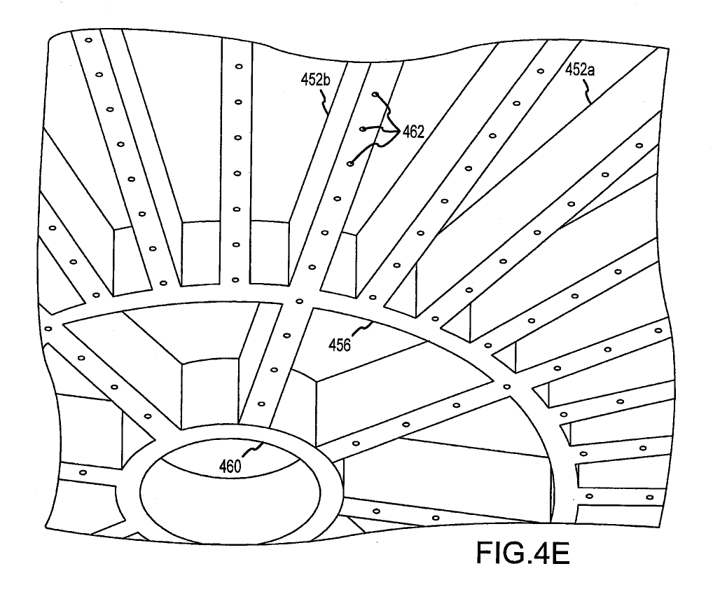

FIG. 4A shows a top view of a configuration of side nozzles in a process system 400 according to embodiments of the invention. In the embodiment shown the side nozzles are radially distributed around the deposition chamber in groups of three nozzles, where the center nozzle 402 extends further into the chamber than two adjacent nozzles 404. Sixteen of these groups of three are evenly distributed around the deposition chamber, for a total of 48 side nozzles. Additional embodiments includes a total number of nozzles ranging from about 12 to about 80 nozzles.

The nozzles 402 and 404 may be spaced above the deposition surface of the substrate wafer. The spacing between the substrate and the nozzles may range from, for example, about 1 mm and about 80 mm (e.g., a range of about 10 mm to about 30 mm). This distance between the nozzles 402 and 404 and the substrate may vary during the deposition (e.g., the wafer may be vertically translated, as well as rotated and/or agitated, during the deposition).

The nozzles 402 and 404 may all be arranged in the same plane, or different sets of nozzles may be located in different planes. The nozzles 402 and 404 may be oriented with a centerline parallel to the deposition surface of the wafer, or they may be tilted upwards or downwards with respect to the substrate surface. Different sets of nozzles 402 and 404 may be oriented at different angles with respect to the wafer.

The nozzles 402 and 404 have distal tips extending into the deposition chamber and a proximal ends coupled to the inner diameter surface of an annular gas ring 406 that supplies precursors to the nozzles. The gas ring may have an inner diameter ranging from, for example, from about 10 inches to about 22 inches (e.g., about 14″ to about 18″, about 15″, etc.). In some configurations, the distal ends of longer nozzles 402 may extend beyond the periphery of the underlying substrate and into the space above the interior of the substrate, while the ends of the shorter nozzles 404 do not reach the substrate periphery. In the embodiment shown in FIG. 4, the distal tip of the shorter nozzles 404 extend to the periphery of a 12″ diameter (i.e., 300 mm) substrate wafer, while the distal tips of the longer nozzles 402 extend an additional 4 inches above the interior of the deposition surface.

The gas ring 406 may have one or more internal channels (e.g., 2 to 4 channels) that provide precursors to the nozzles 402 and 404. For a single channel gas ring, the internal channel may provide precursor to all the side nozzles 402 and 404. For a dual channel gas ring, one channel may provide precursor to the longer nozzles 402, while the second channel provides precursors to the shorter nozzles 404. For each channel the kinds of reactive deposition precursors (e.g., type of organo-silane precursor) and/or the partial pressures, flow rates of carrier gases, may be the same or different depending on the deposition recipe.

FIG. 4B shows a configuration of capped side nozzles 410 in a process system according to embodiments of the invention. Similar to the side nozzles 360 shown in FIG. 3E above, the nozzles 410 are capped at their distal ends extending into the deposition chamber. Precursors flowing through the nozzles exit through a plurality of openings 412 formed in the sidewalls of the nozzle conduits. These openings 412 may be formed in the part of nozzle sidewalls facing the substrate wafer (not shown) to direct the flow of the precursors towards the wafer. The openings 412 may be co-linearly aligned to direct the flow of precursor in the same direction, or they may be formed at different radial positions along the sidewalls to direct the precursor flow at different angles with respect to the underlying wafer.

The nozzles 410 may be fed by an annular gas ring 414 to which the proximal ends of the nozzles 410 are coupled. The gas ring 414 may have a single gas flow channel (not shown) to supply the precursor to all the nozzles 410, or the ring may have a plurality of gas flow channels to supply two or more sets of nozzles 410. For example, in a dual-channel gas ring design, a first channel may supply a first precursor (e.g., a first organosilane precursor) to a first set of nozzles 410 (e.g., the longer set of nozzles shown in FIG. 4B), and a second channel may supply a second precursor (e.g., a second organosilane precursor) to a second set of nozzles 410 (e.g., the shorter set of nozzles shown in FIG. 4B).

FIG. 4C shows a cross-sectional diagram of precursor flow through a side nozzle 420 like one that is shown in FIG. 4B. A precursor 418 (e.g., an organo-silane vapor precursor in a carrier gas from a vapor delivery system) is supplied by a precursor flow channel 416 coupled to the proximal end of the side nozzle 420. The precursor 418 flows through the center of the nozzle conduit and exits through openings 422 in the sidewall. In the nozzle configuration shown, the openings 422 are aligned downwards to direct the flow of precursor 418 towards the underlying wafer substrate (not shown). The openings 422 may have a diameter from about 8 mils to about 200 mils (e.g., about 20 mils to about 80 mils), and a spacing between openings of about 40 mils to about 2 inches (e.g., about 0.25 inches to about 1 inch). The number of openings 422 may vary with respect to the spacing between openings and/or the length of the side nozzle 420.

Embodiments of the invention may also include a single-piece radial precursor manifold that is used in lieu of a set of radial side nozzles like shown in FIG. 4B. An illustration of an embodiment of this precursor manifold 450 (which may also be referred to as a showerhead) is shown in FIG. 4D. The manifold 450 includes a plurality of rectangular conduits 452 that are radially distributed around an outer precursor ring 454. The proximal ends of the conduits 452 may be coupled to the outer ring 454, while the distal ends of the conduits 452 are coupled to an inner annular ring 456.

The rectangular conduits 452 may be supplied with precursor (e.g., one or more organosilicon precursors) by one or more precursor channels (not shown) in the outer precursor ring 454. The precursor exits the conduits 452 though a plurality of openings 462 formed on a side of the conduits. The openings 462 may have a diameter from about 8 mils to about 200 mils (e.g., about 20 mils to about 80 mils), and a spacing between openings of about 40 mils to about 2 inches (e.g., about 0.25 inches to about 1 inch). The number of openings 462 may vary with respect to the spacing between openings and/or the length of the conduits 452.

FIG. 4E shows an enlarged portion of the precursor distribution manifold shown in FIG. 4D. In the embodiment shown, the radially distributed conduits 452a-b may include a first set of conduits 452a whose length extends to the inner annular ring 456, and a second set of conduits 452b whose length extends beyond the inner ring 456 to the center annular ring 460. The first and second sets of conduit 452 may be supplied with different mixtures of precursor.

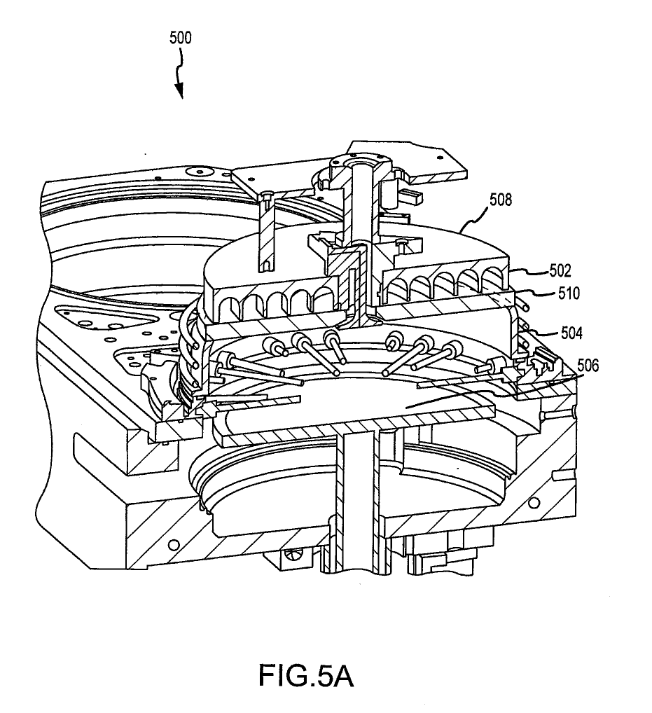

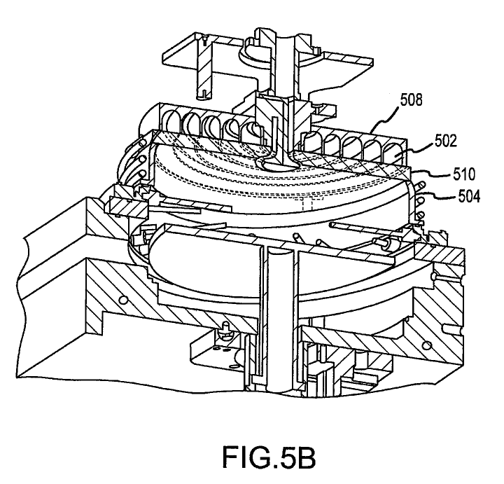

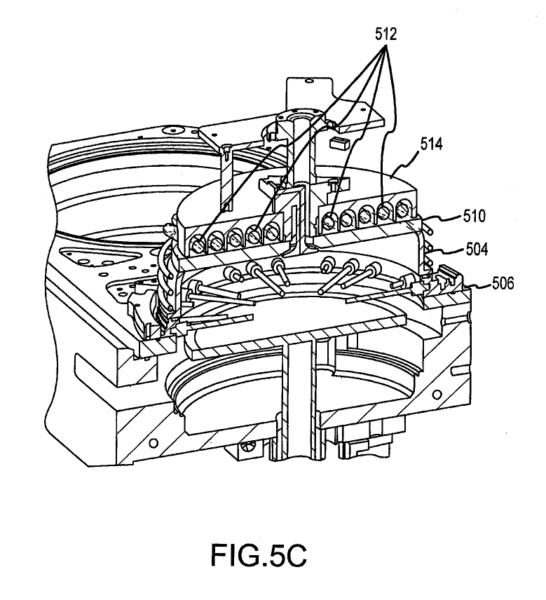

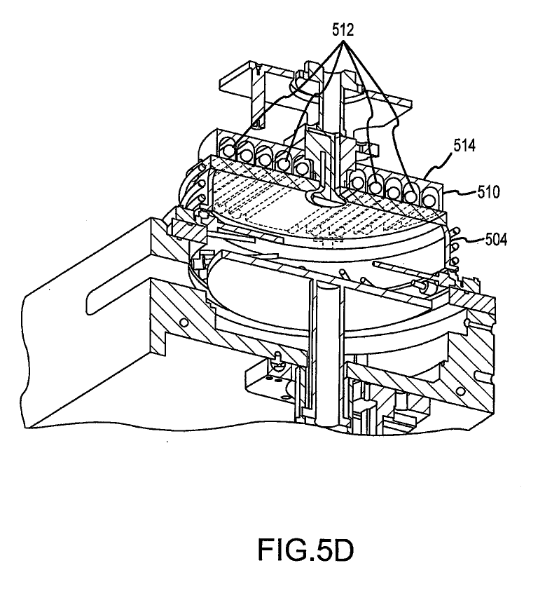

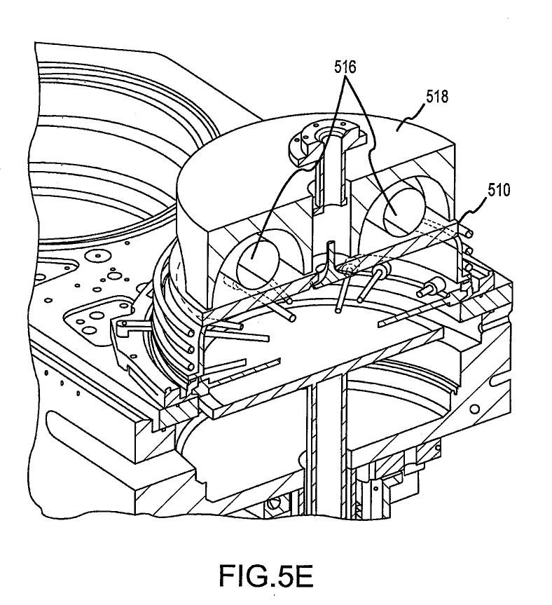

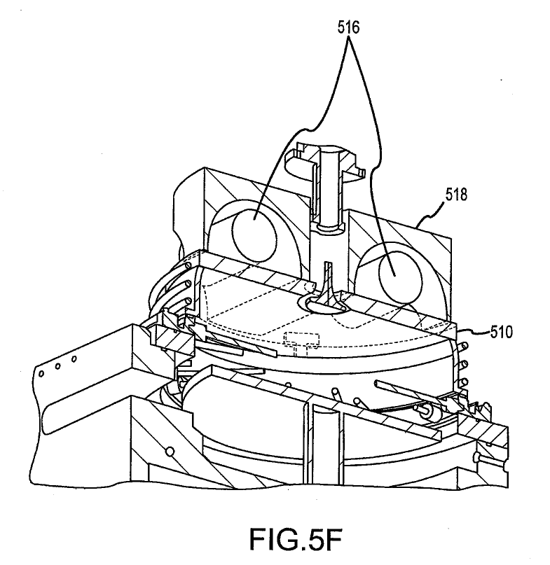

As noted above, embodiments of the deposition systems may also include irradiation systems for curing and/or heating the flowable dielectric film deposited on the substrate. FIGS. 5A and 5B show an embodiment of one such irradiation system 500, which includes a concentric series of annular shaped lamps 502 positioned above a translucent dome 504 and operable to irradiate the underlying substrate 506. The lamps 502 may be recessed in a reflective socket 508 whose lamp-side surfaces have a reflective coating that directs more of the light emitted by the lamp towards the substrate 506. The total number of lamps 502 may vary from a single lamp to, for example, up to 10 lamps.

The lamps 502 may include UV emitting lamps for a curing processes and/or IR emitting lamps for anneal processes. For example, the lamps 502 may be tungsten halogen lamps that may have horizontal filaments (i.e., filaments oriented perpendicular to the axis of symmetry of the bulb of the lamp), vertical filaments (i.e., filaments oriented parallel to the axis of symmetry of the bulb), and/or circular filaments. Different lamps 502 in the reflective socket 508 may have different filament configurations.

Light from the lamps 502 is transmitted through the dome 504 and onto the substrate deposition surface. At least a portion of dome 504 may include an optically transparent window 510 that allows UV and/or thermal radiation to pass into the deposition chamber. The window 510 may be made from, for example, quartz, fused silica, aluminum oxy-nitride, or some other suitable translucent material. As shown in FIGS. 5A-F, the window 510 may be annular in shape and cover the top part of the dome 504 and may have a diameter of, for example, about 8″ to about 22″ (e.g., about 14″). The center of the window 510 may include an inner opening to allow a conduit to pass through into the top of the deposition chamber. The inner opening may have a diameter of, for example, about 0.5″ to about 4″ (e.g., about 1″ in diameter).

FIGS. 5C and 5D show another configuration for lamps 512 having tubular bulbs that are straight instead of annular shaped. The straight lamps 512 may be aligned in parallel and recessed in a reflective socket 514 positioned above the transparent window 510 of dome 504. The reflective socket 514 may have an annular shape and may match the diameter of the underlying window 510. The ends of the lamps 512 may extend beyond the periphery of the socket 514. The number of lamps 512 on either side of the center of window 510 may be equal, and about 4 or more lamps (e.g., about 4 to about 10 lamps) may be used.

FIGS. 5E and 5F show another configuration for the irradiation system that has two large lamps 516 positioned on opposite sides around the center of window 510. The large lamps may be aligned parallel to each other, or at an angle that is less than parallel. The lamps 516 also may be recessed in a reflective socket 518 that aids in directing a portion of the lamp light towards the substrate in the deposition chamber.

The embodiments of the irradiation system shown in FIGS. 5A-F may be used to irradiate the flowable dielectric film during and/or after its deposition on the substrate surface. It may also be used to irradiate the substrate between deposition steps (e.g., a pulse anneal). During the film deposition, the wafer is positioned on the temperature controlled substrate pedestal. The wafer temperature may be set to, for example, about −40° C. to about 200° C. (e.g., about 40° C.). When the substrate is irradiated in a baking (i.e., annealing) process, the temperature of the wafer may increase up to about 1000° C. During this high-temperature anneal, lift-pins on the substrate pedestal may raise the substrate off the pedestal. This can prevent the pedestal from acting as a heat sink and allow the wafer temperature to be increased at a faster rate (e.g., up to about 100° C./second).

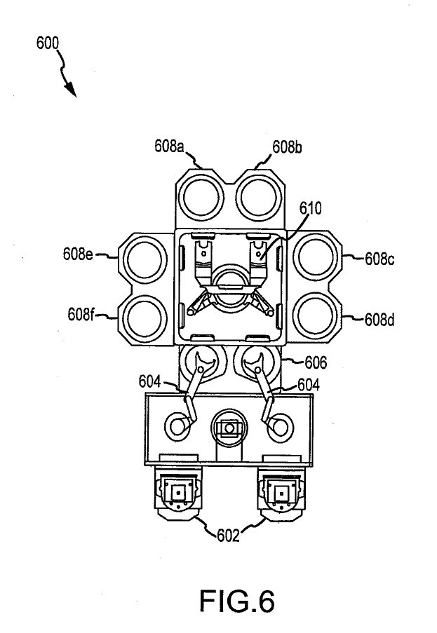

Embodiments of the deposition systems may be incorporated into larger fabrication systems for producing integrated circuit chips. FIG. 6 shows one such system 600 of deposition, baking and curing chambers according to embodiments of the invention. In the figure, a pair of FOOPs 602 supply substrate wafers (e.g., 300 mm diameter wafers) that are received by robotic arms 604 and placed into a low pressure holding area 606 before being placed into one of the wafer processing chambers 608a-f. A second robotic arm 610 may be used to transport the substrate wafers from the holding area 606 to the processing chambers 608a-f and back.

The processing chambers 608a-f may include one or more system components for depositing, annealing, curing and/or etching a flowable dielectric film on the substrate wafer. In one configuration, two pairs of the processing chamber (e.g., 608c-d and 608e-f) may be used to deposit the flowable dielectric material on the substrate, and the third pair of processing chambers (e.g., 608a-b) may be used to anneal the deposited dielectric. In another configuration, the same two pairs of processing chambers (e.g., 608c-d and 608e-f) may be configured to both deposit and anneal a flowable dielectric film on the substrate, while the third pair of chambers (e.g., 608a-b) may be used for UV or E-beam curing of the deposited film. In still another configuration, all three pairs of chambers (e.g., 608a-f) may be configured to deposit an cure a flowable dielectric film on the substrate. In yet another configuration, two pairs of processing chambers (e.g., 608c-d and 608e-f) may be used for both deposition and UV or E-beam curing of the flowable dielectric, while a third pair of processing chambers (e.g. 608a-b) may be used for annealing the dielectric film. It will be appreciated, that additional configurations of deposition, annealing and curing chambers for flowable dielectric films are contemplated by system 600.

In addition, one or more of the process chambers 608a-f may be configured as a wet treatment chamber. These process chambers include heating the flowable dielectric film in an atmosphere that include moisture. Thus, embodiments of system 600 may include wet treatment chambers 608a-b and anneal processing chambers 608c-d to perform both wet and dry anneals on the deposited dielectric film.

### Showerhead Designs

Embodiments of gas delivery and plasma generation systems according to the invention may include showerheads to distribute precursors into the deposition chamber. These showerheads may be designed so that two or more precursors can independently flow though the showerhead without making contact until mixing in the deposition chamber. The showerheads may also be designed so that plasmas may be independently generated behind the faceplate as well as in the deposition chamber. An independent plasma generated between a blocker plate and faceplate of the showerhead may be used to form a reactive precursor species, as well as improve the efficiency of showerhead cleaning processes by activating cleaning species close to the faceplate. Additional details about showerheads designed to independently flow two or more precursors into a deposition region can be found in U.S. patent application Ser. No. 11/040,712 to Jung et al, filed Jan. 22, 2005, and titled “MIXING ENERGIZED AND NON-ENERGIZED GASES FOR SILICON NITRIDE DEPOSITION” the entire contents of which are herein incorporated by reference for all purposes.

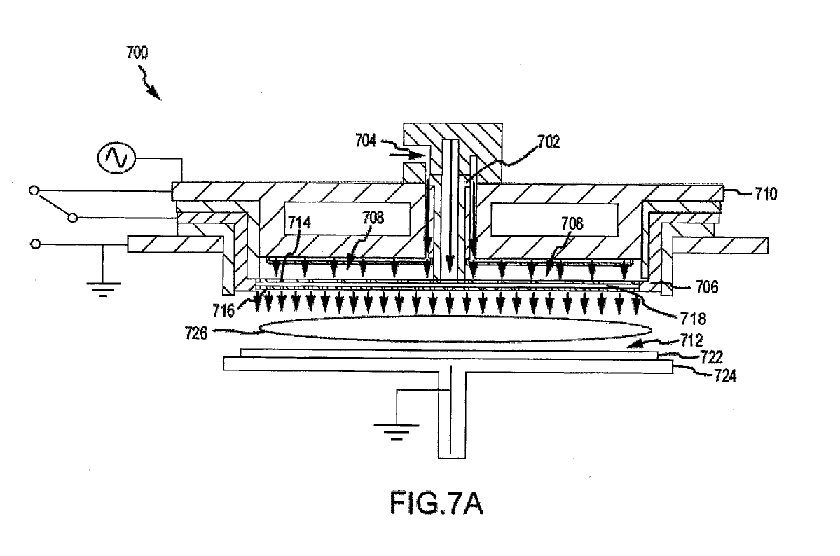

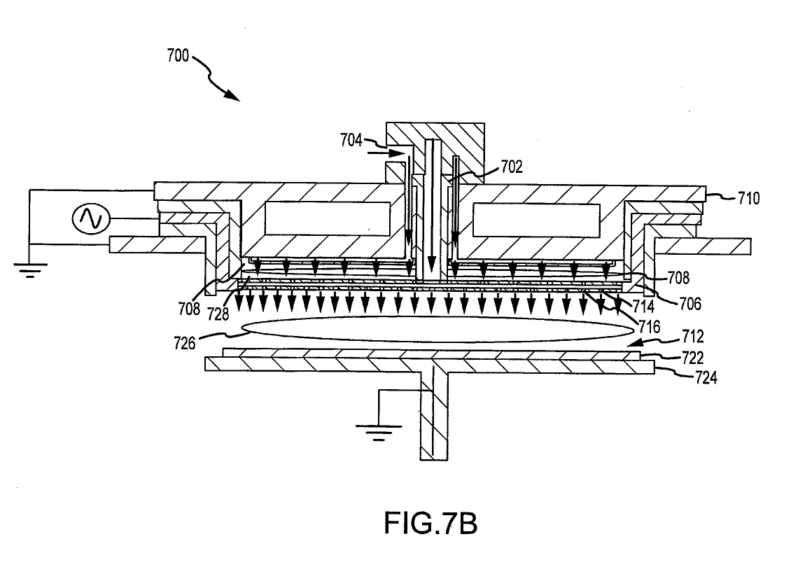

Referring now to FIG. 7A, a simplified cross-sectional schematic of a showerhead system 700 is shown. The showerhead 700 is configured with two precursor inlet ports 702 and 704. The first precursor inlet port 702 is coaxial with the center of the showerhead and defines a flow path for a first precursor down the center of the showerhead and then laterally behind the faceplate 706. The first precursor exits the showerhead into the deposition chamber behind selected openings in the faceplate.

The second precursor inlet port 704 may be configured to flow a second precursor around the first port 702 and into a region 708 between the gasbox 710 and the faceplate 706. The second precursor may then flow from region 708 through selected openings in the faceplate 706 before reaching the deposition region 712. As FIG. 7A shows, the faceplate 706 has two sets of openings: A set of first openings 714 that provide fluid communication between the region 708 and the deposition region, and a second set of openings 716 that provide fluid communication between the first inlet port 702, the faceplate gap 718 and the deposition region 712.

The faceplate 706 may be a dual-channel faceplate that keeps the first and second precursors independent until they leave the showerhead for the deposition region. For example, the first precursors may travel around openings 714 in the faceplate gap 718 before exiting the showerhead through openings 716. Barriers such as a cylindrical port may surround the openings 714 to prevent the first precursor from exiting through these openings. Likewise, the second precursors traveling though openings 714 cannot flow across the faceplate gap 718 and out second openings 716 into the deposition region.

When the precursors exit their respective sets of openings they can mix in the deposition region 712 above the substrate wafer 722 and substrate pedestal 724. The faceplate 706 and pedestal 724 may form electrodes to generate a capacitively coupled plasma 726 in the deposition region above the substrate 722.

The system 700 may also be configured to generate a second plasma 728 behind the in the region 708 behind the face plate. As FIG. 7B shows, this plasma 728 may be generated by applying an rf electric field between the gasbox 710 and the faceplate 706, which form the electrodes for the plasma. This plasma may be made from the second precursor that flows into region 708 from the second precursor inlet port 704. The second plasma 728 may be used to generate reactive species from one or more of the precursors in the second precursor mixture. For example, the second precursor may include an oxygen containing source that forms radical atomic oxygen species in the plasma 728. The reactive atomic oxygen may then flow through faceplate openings 714 into the deposition region where they can mix and react with the first precursor material (e.g., an organo-silane precursor).

In FIG. 7B, the faceplate 706 may act as an electrode for both the second plasma 728 and the first plasma 726 in the deposition region. This dual-zone plasma system may employ simultaneous plasmas to generate a precursor reactive species behind the faceplate 706, and enhance the reactivity of that species with other precursors in the plasma 726. In addition, the plasma 728 can be use to activate a cleaning precursor to make it more reactive with materials that have built up in the showerhead openings. In addition, generating the reactive species in the showerhead instead of the deposition region may reduce the number of unwanted reactions between the active cleaning species and the wall of the deposition chamber. For example, more active fluorine species generated behind the faceplate 706 will react before exiting into the deposition region, where they can migrate to aluminum components of the deposition chamber and form unwanted AlF₃.

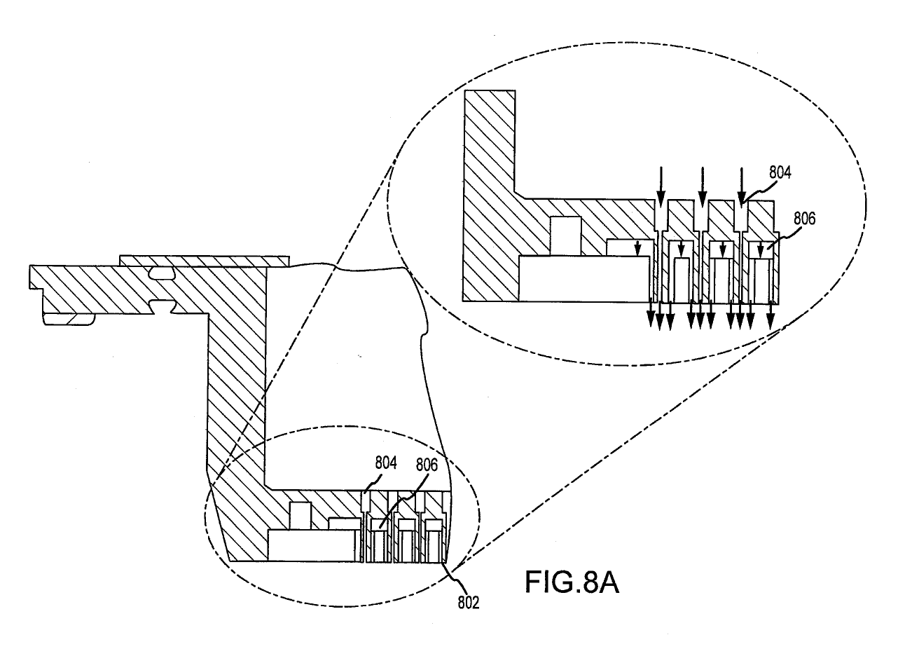

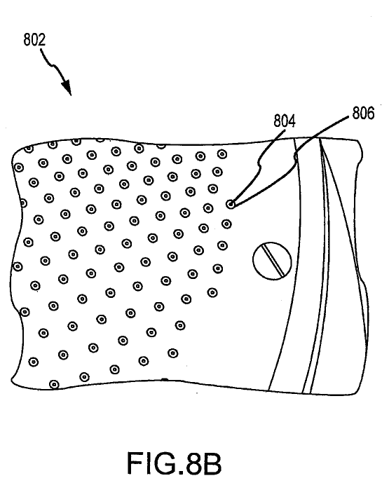

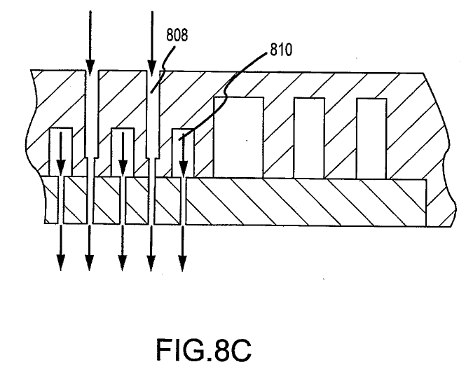

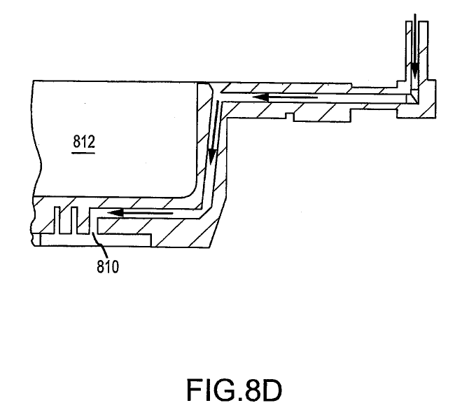

FIGS. 8A and 8C show two configurations for a first and second set of openings 804 and 806 in a faceplate 802 through which two precursor mixtures may independently flow before reaching a deposition region. FIG. 8A shows a cross-section for a concentric-opening design in which the first set of openings 804 pass a first precursor through a straight conduit while the second set of openings 806 pass a second precursor though an concentric annular ring opening that surrounds the first opening. The first and second precursors are isolated from each other behind the faceplate and first mix and react when the emerge from the openings 804 and 806 in the deposition region.

FIG. 8B is a picture of a portion of faceplate 802 that shows an array of first and second opening 804, 806 formed in the faceplate surface. The second annular openings 806 are formed by the gap between the outermost faceplate layer and the tubular walls that define the first openings 804. In the embodiment shown in the picture, the annual gap openings 806 are about 0.003″ around the walls of the center openings 804, which are about 0.028″ in diameter. Of course, other sizes for the first and second openings may also be used. The second precursor passes through these annular openings 806 and surround the precursor emerging from the center openings 804.

FIG. 8C shows a cross-section for a parallel-opening design in which a first set of openings 808 still creates a straight conduit for a first precursor while a second set of parallel adjacent openings 810 provide an independent flow channel for a second precursor. The two sets of openings are isolated from each other so the first and second precursors do not mix and react until exiting the showerhead into the reaction region.

The second precursor exiting the openings 810 may flow from an edge region of the showerhead to the center as shown in FIG. 8D. The channel formed between the second precursor source and the openings 810 is fluidly isolated from the first precursor flowing from region 812 though openings 808 into the deposition region. The second precursor may be provided by one or more fluid channels formed in and/or around the periphery of the showerhead.

Where a range of values is provided, it is understood that each intervening value, to the tenth of the unit of the lower limit unless the context clearly dictates otherwise, between the upper and lower limits of that range is also specifically disclosed. Each smaller range between any stated value or intervening value in a stated range and any other stated or intervening value in that stated range is encompassed within the invention. The upper and lower limits of these smaller ranges may independently be included or excluded in the range, and each range where either, neither or both limits are included in the smaller ranges is also encompassed within the invention, subject to any specifically excluded limit in the stated range. Where the stated range includes one or both of the limits, ranges excluding either or both of those included limits are also included in the invention.

As used herein and in the appended claims, the singular forms “a”, “and”, and “the” include plural referents unless the context clearly dictates otherwise. Thus, for example, reference to “a process” may includes a plurality of such processes and reference to “the nozzle” may include reference to one or more nozzles and equivalents thereof known to those skilled in the art, and so forth.

Also, the words “comprise,” “comprising,” “include,” “including,” and “includes” when used in this specification and in the following claims are intended to specify the presence of stated features, integers, components, or steps, but they do not preclude the presence or addition of one or more other features, integers, components, steps, or groups.

What is claimed is:

1. A substrate processing system comprising:
a processing chamber;
a first electrode;
a pedestal, wherein the pedestal is electrically coupled with ground and configured to operate as a second electrode;
a faceplate;
a first plasma region, wherein the first plasma region is at least partially defined from above by the first electrode and at least partially defined from below by the faceplate; and
a second plasma region, wherein the second plasma region is at least partially defined from above by the faceplate and at least partially defined from below by the pedestal,
wherein the faceplate defines a first plurality of apertures providing fluid access from the first plasma region to the second plasma region, wherein the faceplate defines a second plurality of apertures providing fluid access to the second plasma region without exposure to the first plasma region, and wherein the second plurality of apertures are fluidly accessed from a radial edge of the faceplate.

2. The substrate processing system of claim 1, wherein the faceplate separates the first plasma region from the second plasma region in the processing chamber.

3. The substrate processing system of claim 1, wherein the faceplate comprises a third electrode that is shared between the first plasma region and the second plasma region.

4. The substrate processing system of claim 1, wherein the first electrode and the faceplate are configured to generate an RF plasma in the first plasma region.

5. The substrate processing system of claim 1, wherein the faceplate and the second electrode are configured generate an RF plasma in the second plasma region.

6. The substrate processing system of claim 1, further comprising a distribution plate positioned between the first electrode and the faceplate.

7. The substrate processing system of claim 6, wherein the distribution plate is electrically coupled with the first electrode.

8. The substrate processing system of claim 1, wherein the substrate processing system further comprises a gas inlet configured to supply a first precursor to the first plasma region.

9. The substrate processing system of claim 8, wherein the gas inlet is further configured to provide a second precursor through the gas inlet fluidly separate from the first precursor.

10. The substrate processing system of claim 1, wherein each aperture of the second plurality of apertures is coaxially aligned with an aperture of the first plurality of apertures.

11. The substrate processing system of claim 1, wherein each aperture of the first plurality of apertures is characterized by a first diameter fluidly accessed from the first plasma region and a second diameter less than the first fluidly accessing the second plasma region.

12. The substrate processing system of claim 1, wherein the system further comprises a temperature control system configured to maintain the pedestal at a temperature ranging from about −40° C. to about 200° C.

13. A substrate processing chamber comprising:
an inlet assembly;
a first electrode defining a central channel within which the inlet assembly is at least partially disposed;
a pedestal, wherein the pedestal is electrically coupled with ground and configured to operate as a second electrode;
a faceplate;
a first plasma region, wherein the first plasma region is at least partially defined from above by the first electrode and at least partially defined from below by the faceplate; and
a second plasma region, wherein the second plasma region is at least partially defined from above by the faceplate and at least partially defined from below by the pedestal,
wherein the faceplate defines a first plurality of apertures providing fluid access from the first plasma region to the second plasma region, wherein the faceplate defines a second plurality of apertures providing fluid access to the second plasma region without exposure to the first plasma region, and wherein the second plurality of apertures are fluidly accessed from a radial edge of the faceplate.

14. The substrate processing chamber of claim 13, wherein the faceplate is electrically operable as a third electrode that is shared between the first plasma region and the second plasma region.

15. The substrate processing chamber of claim 14, wherein the faceplate is switchably coupled with a power source and ground.

16. The substrate processing chamber of claim 13, wherein the first electrode and the faceplate are electrically operable to generate an RF plasma in the first plasma region.

17. The substrate processing chamber of claim 13, wherein the faceplate and the second electrode are electrically operable to generate an RF plasma in the second plasma region.

18. The substrate processing chamber of claim 13, further comprising a distribution plate positioned between the first electrode and the faceplate.

19. The substrate processing chamber of claim 18, wherein the distribution plate is electrically coupled with the first electrode.

20. The substrate processing chamber of claim 13, wherein the chamber further comprises a temperature control system that maintains the pedestal at a temperature ranging from about −40° C. to about 200° C.
